(19) United States
(12) Patent Application Publication
(10) Pub. No.: US 2012/0107997 A1
(43) Pub. Date: May 3, 2012

(54) METHOD OF MANUFACTURING SOLAR CELL

(76) Inventors: Young-Jin KIM, Yongin-si (KR); Dong-Seop Kim, Yongin-si (KR); Doo-Youl Lee, Yongin-si (KR); Jun-Hyun Park, Yongin-si (KR); Sang-Ho Kim, Yongin-si (KR); Ju-Hyun Jeong, Yongin-si (KR); Young-Soo Kim, Yongin-si (KR); Chan-Bin Mo, Yongin-si (KR); Young-Su Kim, Yongin-si (KR); Myeong-Woo Kim, Yongin-si (KR); Sang-Joon Lee, Yongin-si (KR)

(21) Appl. No.: 13/239,197

(22) Filed: Sep. 21, 2011

(30) Foreign Application Priority Data
Oct. 29, 2010 (KR) 10-2010-0106954

(51) Int. Cl. H01L 31/18

(52) U.S. Cl. 438/72; 257/E31.127

(57) ABSTRACT

In a method of manufacturing a solar cell, a first dopant layer is formed on a lower surface of a substrate and a diffusion-preventing layer is formed on an upper surface of the substrate. Then, the first dopant layer is patterned to expose portions of the lower surface of the substrate, and a second dopant layer is formed on the exposed portion of the lower surface of the substrate. A third dopant layer is formed on the diffusion-preventing layer, and the substrate is heated to diffuse dopants from the first, second, and third dopant layers into the substrate, thereby forming semiconductor areas in the substrate.

### CROSS-REFERENCE TO RELATED APPLICATION

This application claims priority to, and the benefit of, Korean Patent Application No. 10-2010-0106954 filed on Oct. 29, 2010, the contents of which are herein incorporated by reference in their entirety.

### BACKGROUND

1. Field of Disclosure

Embodiments of the present invention relate generally to solar cells. More specifically, embodiments of the present invention relate to methods of manufacturing rear-electrode type solar cells.

2. Description of the Related Art

Photoelectric devices are used to convert solar (or other ambient light) energy into electrical energy. One type of photoelectric device, the solar cell, converts solar energy into electrical energy via a structure that utilizes a p-type semiconductor layer coupled with an n-type semiconductor layer, or a structure that employs an intrinsic semiconductor layer disposed between the p-type semiconductor layer and the n-type semiconductor layer. The semiconductor layers absorb solar radiation and generate electrons and holes according to the photoelectric effect. When a bias is applied to the solar cell, the solar cell produces an electrical current due to the generated electrons and holes.

The photoelectric conversion efficiency of the solar cell can be defined according to a ratio of an amount of electrical current generated by the solar cell, to the corresponding amount of light provided to the solar cell. The photoelectric conversion efficiency of the solar cell is often a useful factor in improving the solar cell, since it is related to the capability of the solar cell to produce electrical energy.

### SUMMARY

Exemplary embodiments of the present invention provide a rear-electrode type solar cell that requires fewer manufacturing processes for its fabrication.

According to the exemplary embodiments, a method of manufacturing a solar cell is provided as follows. A first dopant layer is formed on a lower surface of a substrate and a diffusion-preventing layer is formed on an upper surface of the substrate. The diffusion-preventing layer may be formed of undoped silicon. Before the forming of the diffusion-preventing layer, the upper surface of the substrate may be textured to have shapes that are generally pyramid shapes.

Then, the first dopant layer is patterned to expose portions of the lower surface of the substrate, a second dopant layer is formed on the exposed portions of the lower surface of the substrate, and a third dopant layer including an n-type dopant is formed on the diffusion-preventing layer. The second and third dopant layers may be formed during a single process.

The substrate is heated to diffuse dopants of the first, second, and third dopant layers into the substrate, and to form a plurality of semiconductor areas in the lower surface of the substrate, so that a recombination-preventing layer doped with n-type dopant is formed on the upper surface of the substrate. Then, the first to third dopant layers and the diffusion-preventing layer are removed. An anti-reflection layer is formed on the recombination-preventing layer and a passivation layer is formed on the semiconductor areas. The anti-reflection layer and the passivation layer may be formed of the same material, such as silicon nitride.

According to the above, the recombination-preventing layer and p-type and n-type semiconductor areas may be substantially simultaneously formed through the same diffusion process, and the anti-reflection layer and the passivation layer may be formed under the same condition. Thus, manufacturing processes for the solar cell may be simplified, thereby improving productivity of the solar cell. In addition, since each of the anti-reflection layer and the passivation layer has a single-layer structure of silicon nitride, manufacturing cost for the solar cell may be reduced.

### BRIEF DESCRIPTION OF THE DRAWINGS

The above and other advantages of the present invention will become readily apparent by reference to the following detailed description when considered in conjunction with the accompanying drawings wherein:

FIG. 1 is a sectional view showing a rear-electrode type solar cell according to a first exemplary embodiment of the present invention;

FIG. 2 is a flowchart showing a method of manufacturing a solar cell according to a first exemplary embodiment of the present invention;

FIGS. 3A to 3N are sectional views showing a method of manufacturing a solar cell according to a first exemplary embodiment of the present invention;

FIG. 4 is a graph showing a variation of a surface resistance value according to a thickness of a diffusion preventing layer;

FIGS. 5A to 5H are sectional views showing a method of manufacturing a solar cell according to a second exemplary embodiment of the present invention;

FIGS. 6A to 6F are sectional views showing a method of manufacturing a solar cell according to a third exemplary embodiment of the present invention; and

FIGS. 7A to 7C are sectional views showing a method of manufacturing a solar cell according to a fourth exemplary embodiment of the present invention.

### DETAILED DESCRIPTION

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

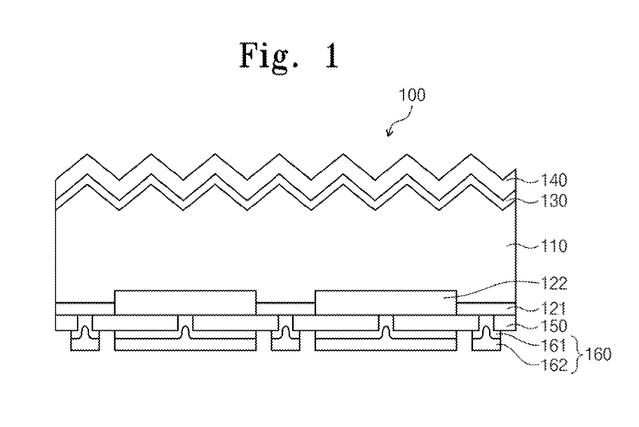

FIG. 1 is a sectional view showing a rear-electrode type solar cell 100 according to a first exemplary embodiment of the present invention.

Referring to FIG. 1, the rear-electrode type solar cell 100 includes a substrate 110, a plurality of semiconductor areas 121 and 122, a passivation layer 150, metal electrodes 160, a recombination-preventing layer 130, and an anti-reflection layer 140.

The semiconductor areas 121 and 122 are formed on a lower surface of the substrate 110. The semiconductor areas 121 and 122 include n-type semiconductor areas 121 and p-type semiconductor areas 122, where the n-type semiconductor areas 121 are alternately arranged with the p-type semiconductor areas 122. In FIG. 1, the n-type and p-type semiconductor areas 121 and 122 have a rectangular shape, but they are not limited thereto, and the invention contemplates semiconductor areas of any shapes.

The substrate 110 is an n-type wafer. The substrate 110 absorbs light from external sources, and generates electron-hole pairs in the substrate 110 as a result (photoelectric effect). The generated electrons move to the n-type semiconductor areas 121, and the holes move to the p-type semiconductor areas 122, so that a voltage difference occurs between the n-type semiconductor area 121 and the p-type semiconductor area 122. An upper surface of the substrate 110 may be textured to have pyramid shapes with various sizes, thereby improving light collection ability thereof. In FIG. 1, the pyramid shapes have the same size, but the invention is not limited to such a configuration, and instead includes any suitable shapes or combinations of shapes.

The passivation layer 150 is disposed on the semiconductor areas 121 and 122. In this embodiment, the passivation layer 150 has a single-layer structure of silicon nitride.

Each of the metal electrodes 160 is electrically connected to a corresponding semiconductor area 121 or 122 to connect the solar cell 100 to an external circuit, and thus transmits currents generated in the semiconductor areas. The metal electrodes 160 may be directly connected to the semiconductor areas 121 and 122. In this embodiment, each of the metal electrodes 160 includes a first metal layer 161 and a second metal layer 162. As an example, the first metal layer 161 may have a triple-layer structure of aluminum (Al)/titanium tungsten alloy (TiW)/copper (Cu), and the second metal layer 162 may have a double-layer structure of copper (Cu)/tin (Sn). A more detailed description of the first and second metal layers 161 and 162 is provided below.

The recombination-preventing layer 130 is disposed on the upper surface of the substrate 110. The recombination-preventing layer 130 is a silicon layer doped with an n-type impurity. The recombination-preventing layer 130 thus inhibits or prevents electrons generated by the photoelectric effect from moving toward the upper surface of the substrate 110 and from recombining with the holes in the substrate 110, thereby improving the conversion efficiency of the solar cell 100.

The anti-reflection layer 140 is disposed on the recombination-preventing layer 130 to lower the reflectivity of the substrate 110 with respect to incident light, and to thus increase the amount of light incident to the solar cell 100. The anti-reflection layer 140 may be, for example, a silicon nitride (SiNx) layer.

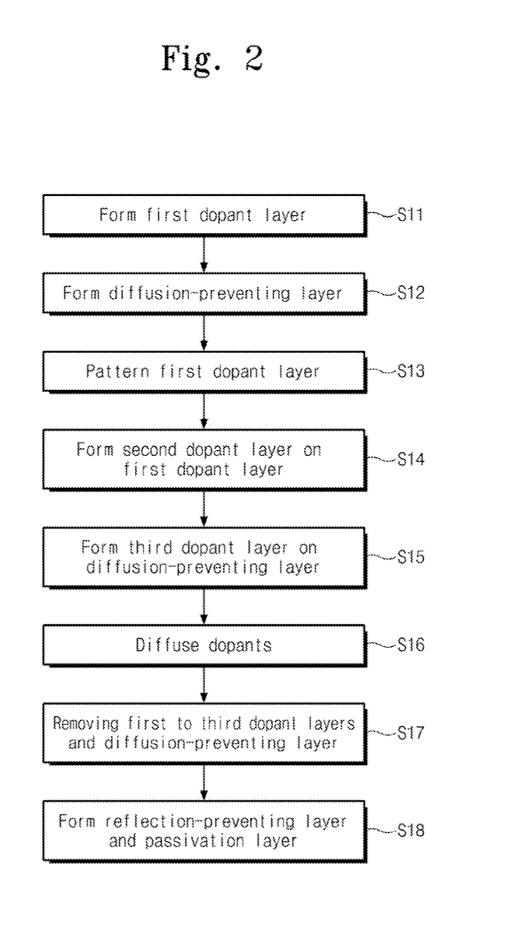

FIG. 2 is a flowchart showing a method of manufacturing a solar cell according to a first exemplary embodiment of the present invention.

Referring to FIG. 2, a first dopant layer is formed on the lower surface on the substrate (S11) and a diffusion-preventing layer is formed on the upper surface of the substrate (S12). Then, the first dopant layer is patterned to expose n-type areas of the lower surface of the substrate (S13). Next, a second dopant layer is formed on the exposed areas (S14), and a third dopant layer that includes n-type dopants is formed on the diffusion-preventing layer (S15).

Then, the substrate, including the first to third dopant layers and the diffusion-preventing layer, is heated. This heating diffuses dopants from the first to third dopant layers into the substrate, so that the above-described semiconductor areas are formed at the lower surface of the substrate, and the recombination-preventing layer is formed at the upper surface of the substrate (S16).

After that, the first to third dopant layers and the diffusion-preventing layer are removed (S17). This leaves the recombination-preventing layer on the upper surface of the substrate, and the diffusion-preventing layer and the passivation layer on the semiconductor areas (S18).

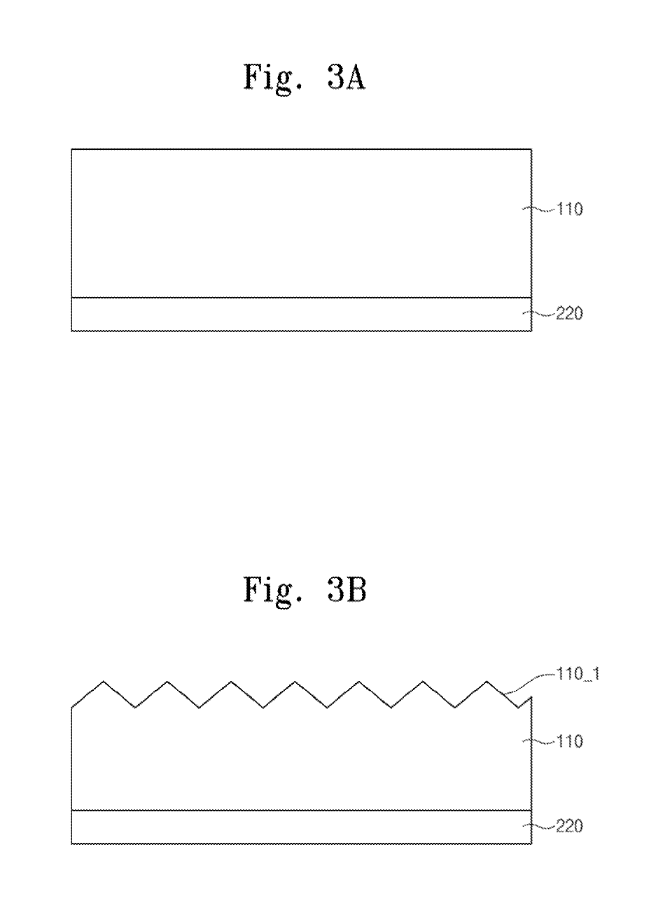

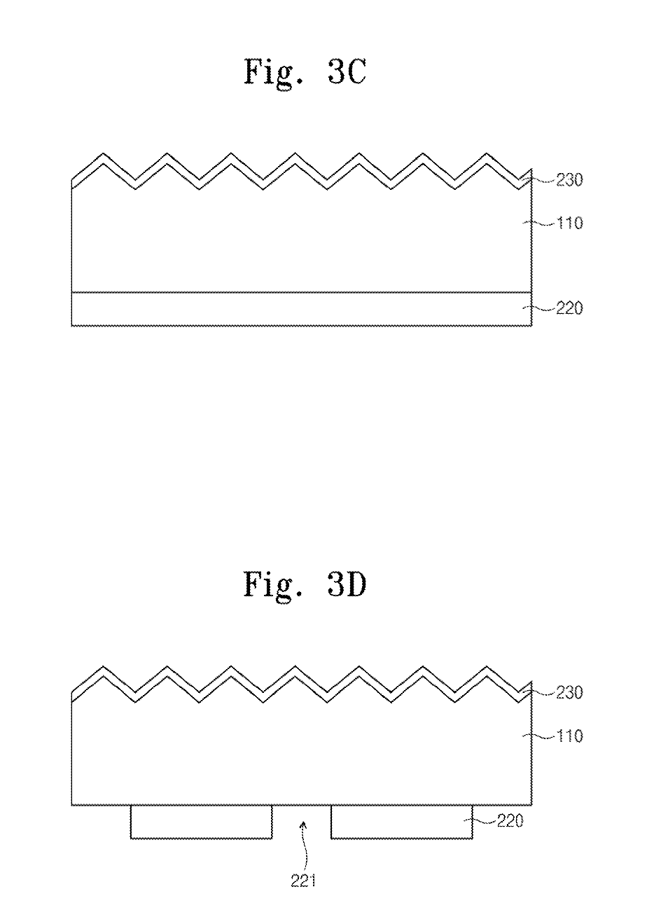

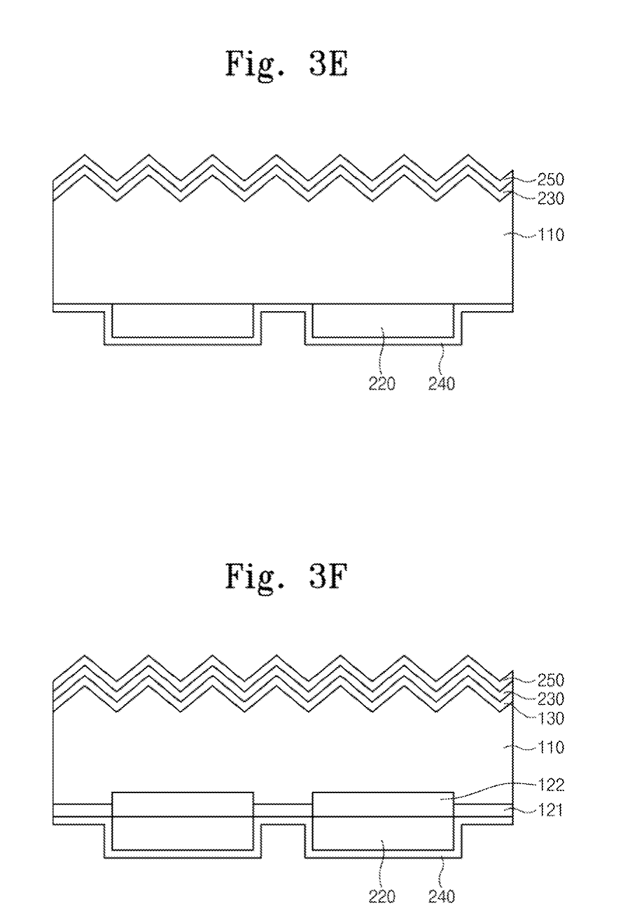

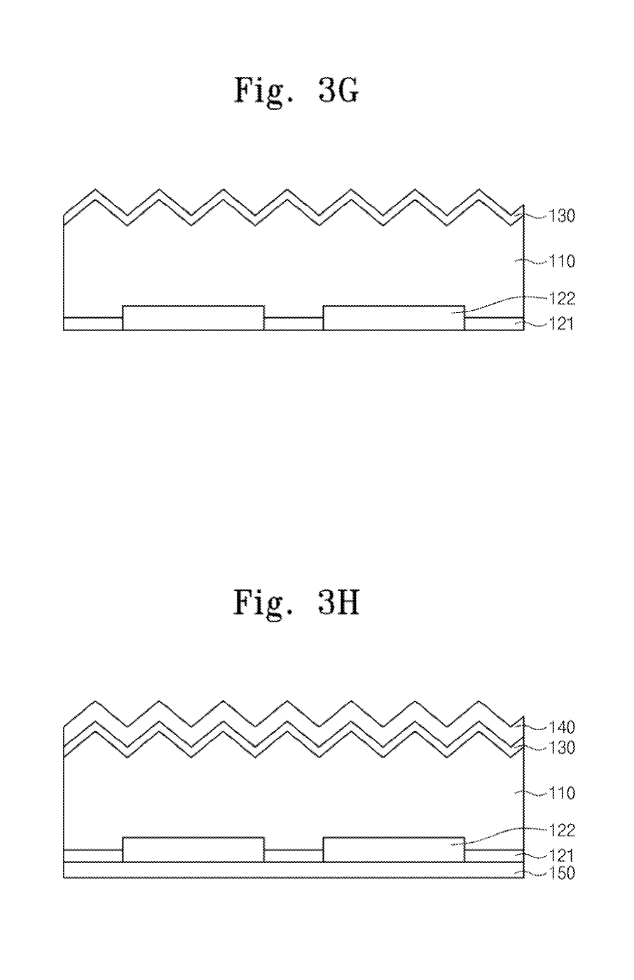

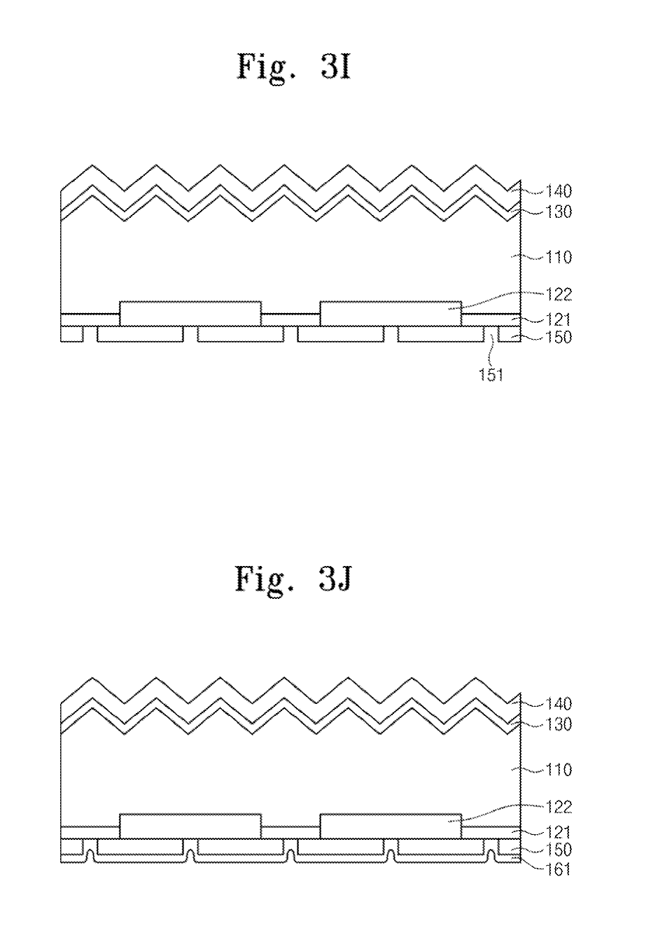

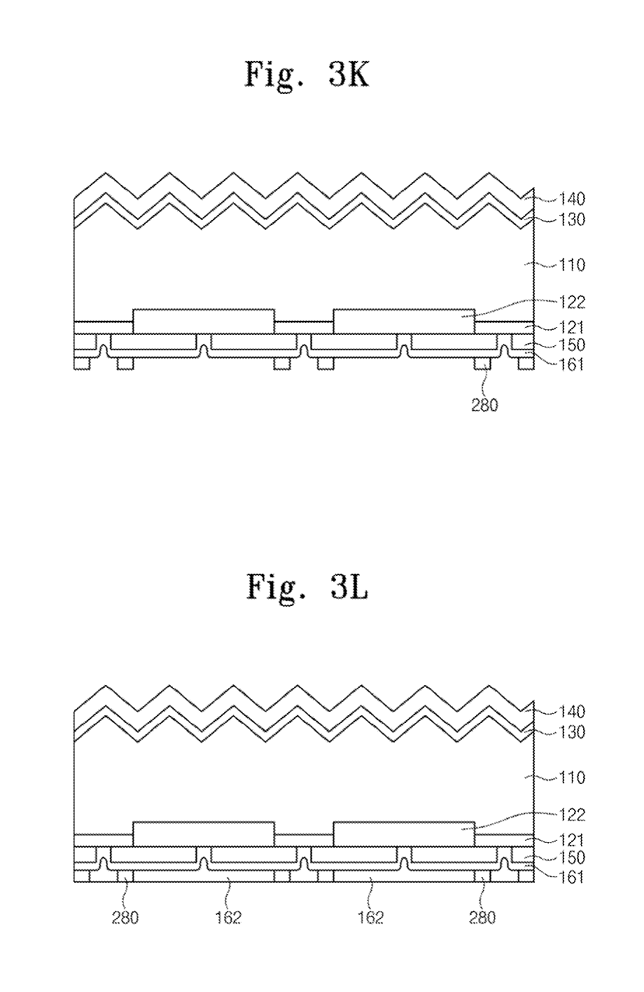

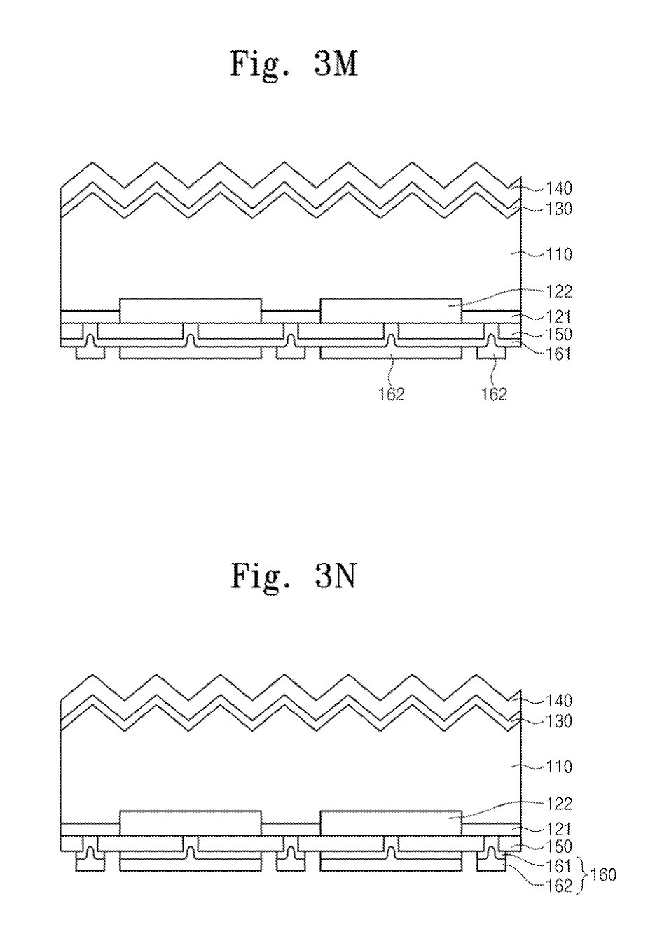

The above-described method of manufacturing the solar cell is now described in further detail with reference to FIGS. 1 and 3A to 3N.

FIGS. 3A to 3N are sectional views showing a method of manufacturing a solar cell according to a first exemplary embodiment of the present invention.

Referring to FIG. 3A, a first dopant layer 220 is formed on the lower surface of the substrate 110. The substrate 110 may be an n-type silicon wafer and the first dopant layer 220 may include p-type dopants. As an example, the first dopant layer 220 may include boron, and particularly may be a boron silicate glass (BSG) layer. The first dopant layer 220 may be formed by a semiconductor process, such as a chemical vapor deposition process, a sputtering process, etc., though the layer 220 can be formed in any suitable manner. For example, the first dopant layer 220 may be formed by an inkjet printing process or a screen printing process.

The first dopant layer 220 may have a thickness sufficient to prevent damage to the first dopant layer 220 by sodium hydroxide solution used to texture the upper surface of the substrate 110. That is, the first dopant layer 220 is made thick enough that a sufficient amount of this layer will remain undamaged upon application of sodium hydroxide used in texturing.

Referring to FIG. 3B, the upper surface of the substrate 110 is textured to form pyramid shapes 110_1. The upper surface of the substrate 110 is textured by a wet etching process using a mixture of a sodium hydroxide solution and an isopropyl alcohol solution. In FIG. 2, the pyramid shapes 110_1 have generally the same size, but the sizes and exact shapes of these protrusions can vary. That is, various-size pyramid shapes may be formed, as well as other shapes.

In detail, when the substrate 110 is dipped into the mixture of sodium hydroxide solution and isopropyl alcohol solution, portions of the upper surface of the substrate 110 are more rapidly etched than other portions. The isopropyl alcohol solution increases hydrophilicity of the wafer. During the texturing process, the lower surface of the substrate 110 is protected by the first dopant layer 220, so that the lower surface of the substrate 110 is not textured.

Referring to FIGS. 1 and 3C, a diffusion-preventing layer 230 is deposited on the textured upper surface of the substrate 110. In the present exemplary embodiment, the diffusion-preventing layer 230 may be a silicon layer not doped with impurities (i.e., undoped silicon). The diffusion-preventing layer 230 may prevent the dopants included in the third dopant layer 250 from being diffused into the substrate 110 during the following diffusion process. The diffusion-preventing layer 230 may be deposited on the upper surface of the substrate 110 through a chemical vapor deposition process.

Referring to FIGS. 1 and 3D, the first dopant layer 220 is patterned to form openings 221 therethrough. The openings 221 are formed corresponding to areas in which the n-type semiconductor areas 121 are to be formed.

In order to form the openings 221 through the first dopant layer 220, a photolithography process and an etching process may be used. In detail, a photoresist is coated over the first dopant layer 220 and the photoresist is developed after exposure to light using a mask. Then, when the first dopant layer 220 is etched, the openings 221 may be formed. The etching process for the first dopant layer 220 may be a wet etching process, although any etching process is contemplated.

Referring to FIGS. 3D and 3E, the second dopant layer 240 is formed on the first dopant layer 220 and the openings 221, and the third dopant layer 250 is formed on the diffusion-preventing layer 230. The second and third dopant layers 240 and 250 may include n-type dopants. For example, the second and third dopant layers 240 and 250 may include phosphorus (P), and the second and third dopant layers 240 and 250 may be a phosphorus silicate glass (PSG, P₂O₅). The second dopant layer 240 is used as a source of dopants for forming the n-type semiconductor areas 121 via a diffusion process, and the third dopant layer 250 is used as a source of dopants for forming the recombination-preventing layer 130, also via a diffusion process. These diffusions processes are further explained below.

The second and third dopant layers 240 and 250 may be formed by a chemical vapor deposition process using a phosphoryl chloride (POCl₃) gas at high temperature. In particular, when the substrate 110 is exposed to a vapor of the phosphoryl chloride (POCl₃) gas at high temperature, the third dopant layer 250 is formed upon the diffusion-preventing layer 230, and the second dopant layer 240 is formed on the first dopant layer 220 and the openings 221.

The deposition process is performed in a thermal furnace and, as is described above, may deposit layers on both the upper and lower surfaces of substrate 110. Therefore, the phosphoryl chloride (POCl₃) gas may be substantially simultaneously applied to both the upper and lower surfaces. Accordingly, the second and third dopant layers 240 and 250 may be formed by the same process. In addition, since the second and third dopant layers 240 and 250 are formed under the same process conditions, the second dopant layer 240 may have substantially the same doping concentration as the third dopant layer 250.

Referring to FIG. 3F, the substrate 110 is then heated to diffuse the dopants in the first, second and third dopant layers 220, 240, and 250 into the substrate 110, thereby forming the semiconductor areas 121 and 122 and the recombination-preventing layer 130.

In more detail, when the first to third dopant layers 220, 240, and 250 are heated, the dopants in the first to third dopant layers 220, 240, and 250 diffuse into the substrate 110. As a result, the p-type semiconductor areas 122 are formed in areas in which the substrate 110 makes contact with the first dopant layer 220, and the n-type semiconductor areas 121 are formed in areas in which the substrate 110 makes contact with the second dopant layer 240. In addition, the recombination-preventing layer 130 is formed under the diffusion-preventing layer 230 due to the diffusion of dopants from the third dopant layer 250.

Since the diffusion process is carried out after forming the first, second, and third dopant layers 220, 240, and 250, plural layers, for example, the recombination-preventing layer 130 and the semiconductor areas 121 and 122, may be formed through a one-time diffusion process. That is, a single diffusion process acts to form multiple layers/areas 121, 122, 130.

In addition, since the substrate 110 directly contacts the second dopant layer 240 at the areas in which the n-type semiconductor areas 121 are formed, the dopants in the second dopant layer 240 may be diffused directly into the substrate 110. However, the diffusion-preventing layer 230 is disposed between the recombination-preventing layer 130 and the third dopant layer 250. In other words, the dopants in the third dopant layer 250 are diffused into substrate 110 through the diffusion-preventing layer 230. Thus, a difference in diffusion speed occurs between the dopants from the second dopant layer 240 and the dopants from the third dopant layer 250. Accordingly, although the second and third dopant layers 240 and 250 have the same doping concentration, the recombination-preventing layer 130 has a doping concentration that is lower than that of the n-type semiconductor areas 121. Additionally, the dopant concentration of the recombination-preventing layer 130 may be controlled by adjusting the thickness of the diffusion preventing layer 230.

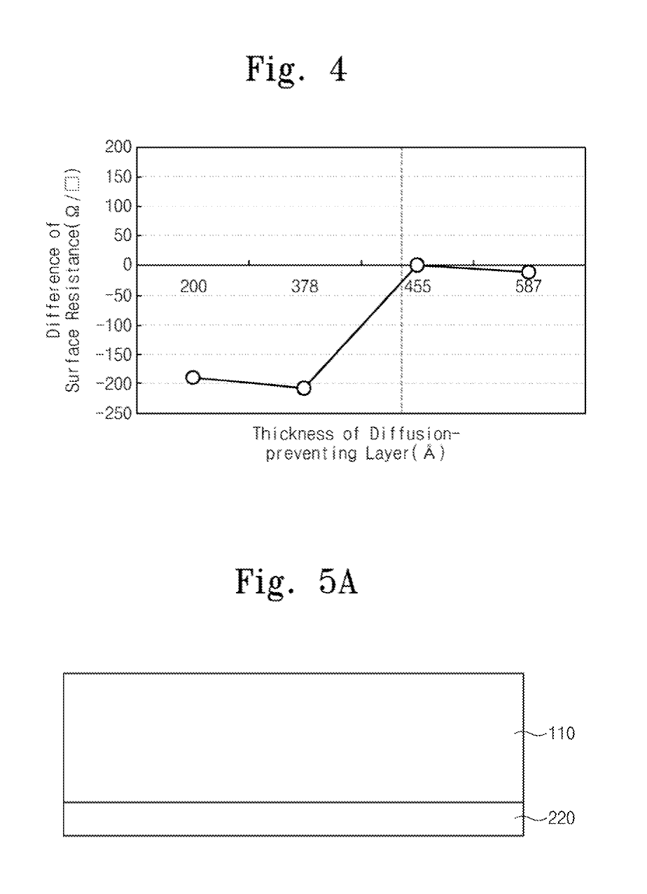

Hereinafter, the dopant concentration of the recombination-preventing layer 130 as a function of the thickness of the diffusion-preventing layer 230 is described with reference to FIGS. 3F and 4.

FIG. 4 is a graph showing the variation in a surface resistance value according to a thickness of a diffusion preventing layer. In FIG. 4, the horizontal axis indicates the thickness (Å) of the diffusion-preventing layer 230 and a vertical axis indicates the corresponding difference in surface resistances (Ω/□) of the upper surface of the substrate 110 from before to after the diffusion process. In the case that the surface resistance difference (Ω/□) is measured as a negative value, it means that the recombination-preventing layer 130 was formed after the diffusion process, and in the case that the surface resistance difference (Ω/□) is measured as a positive value or closer to zero (0), it means that the recombination-preventing layer 130 was not formed. Accordingly, the graph shown in FIG. 4 may represent the doping concentration of the recombination-preventing layer 130 as a function of the thickness of the diffusion-preventing layer 230.

Referring to FIGS. 3F and 4, when the thickness of the diffusion-preventing layer 230 is in a range of about 200 angstroms to about 378 angstroms, the surface resistance after the diffusion process is measured to be about 200 (Ω/□) lower than that before the diffusion process, i.e. the difference in surface resistance is about −200 Ω/□. However, when the thickness of the diffusion-preventing layer 230 is equal to or larger than about 450 angstroms, the surface resistance difference (Ω/□) is closer to zero (0). Thus, when the thickness of the diffusion-preventing layer 230 is equal to or larger than about 450 angstroms, it is determined that the recombination-preventing layer 130 was not formed. In this case, the thickness of the diffusion-preventing layer 230 at which the recombination-preventing layer 130 is not formed depends upon process conditions.

Referring to FIGS. 3F and 3G, the first to third dopant layers 220, 240, and 250 and the diffusion-preventing layer 230 are removed by using, for example, hydrogen fluoride (HF). The recombination-preventing layer 130 and the semiconductor areas 121 and 122 remain on the substrate 110.

Referring FIG. 3H, the anti-reflection layer 140 is formed on the recombination-preventing layer 130, and the passivation layer 150 is formed on the semiconductor areas 121 and 122. The anti-reflection layer 140 and the passivation layer 150 may be formed by, for example, a chemical vapor deposition process.

More particularly, the substrate 110 shown in FIG. 3G is placed in a thermal furnace that allows simultaneous deposition on both sides of substrate 110, and then a silicon nitride (SiNx) layer is deposited on the recombination-preventing layer 130 and the semiconductor areas 121 and 122 using silane and ammonia gas mixtures. Thus, the anti-reflection layer 140 and the passivation layer 150 may both be formed of silicon nitride (SiNx), through the same process.

FIGS. 3I to 4N show the formation of metal electrodes on the solar cell. Referring to FIGS. 1 and 3I, the passivation layer 150 is patterned to form contact holes 151, through which portions of the semiconductor areas 121 and 122 are exposed, respectively corresponding to areas in which the metal electrodes 160 are to be formed. The contact holes 151 may be formed by photolithography and etch processes, in known manner. The metal electrodes 160 may be directly connected to the semiconductor areas 121 and 122, respectively, through the contact holes 151.

Referring to FIGS. 1 and 3J, the first metal layer 161 is formed on the passivation layer 150. As an example, the first metal layer 161 may have a triple-layer structure with aluminum (Al)/titanium tungsten alloy (TiW)/copper (Cu) layers. In order to form a first metal layer 161 with this structure, the aluminum layer, the titanium-tungsten alloy layer, and the copper layer are sequentially formed on the passivation layer 150 by sputtering processes. The aluminum layer is formed to improve adhesion between the first metal layer 161 and the semiconductor areas 121 and 122, and the titanium-tungsten alloy layer is formed to prevent reaction between the aluminum layer and the copper layer. The copper layer is used as a seed layer when the second metal layer 162 is formed.

Referring to FIGS. 1 and 3K, a print-preventing layer 280 is formed corresponding to boundaries between the semiconductor areas 121 and 122, to prevent the second metal layer 162 from being formed at these boundaries. The print-preventing layer 280 includes a polymer compound. The print-preventing layer 280 may be formed by a chemical vapor deposition process and an etching process.

Referring to FIG. 3L, the second metal layer 162 is formed on the first metal layer 161 except at those areas upon which the print-preventing layer 280 is formed. In the present exemplary embodiment, the second metal layer 162 may have a double-layer structure of copper (Cu)/tin (Sn). The tin layer serves as a mask layer to protect the copper layer from being damaged during removal of the print-preventing layer 280.

The second metal layer 162 may be formed by a screen printing process. To this end, a screen mask is disposed on the first metal layer 161, and then a paste is squeezed onto the first metal layer 161, thereby forming the second metal layer 162 in those areas in which the print-preventing layer 280 is not formed.

Referring to FIG. 3M, the print-preventing layer 280 is removed by, for example, an etching process such as a wet etching process. The first metal layer 161 is thus exposed in those areas where the print-preventing layer 280 used to be present.

Referring to FIG. 3N, the exposed portions of the first metal layer 161 are etched back. Since the metal electrodes 160 are connected to each other by the first metal layer 161 after the process shown in FIG. 3M, the first metal layer 161 is removed to separate the metal electrodes 160 from each other and prevent electrical shorts. The exposed portions of the first metal layer 161 may be removed by, for example, a wet etching process.

As described above, the second and third dopant layers 240 and 250 are formed by a single deposition process, and the recombination-preventing layer 130 and the n-type and p-type semiconductor areas 121 and 122 are also formed by a single diffusion process. In addition, the anti-reflection layer 140 and the passivation layer 150 are formed through the same (i.e., a single) process. Accordingly, fabrication of the solar cell may be simplified, thereby improving productivity and cost of the solar cell. In addition, since the anti-reflection layer 140 and the passivation layer 150 each have a single-layer structure of silicon nitride, the manufacturing cost for the solar cell may be reduced as compared to cells whose anti-reflection layer 140 and the passivation layer 150 have double-layer structures of silicon oxide/silicon nitride.

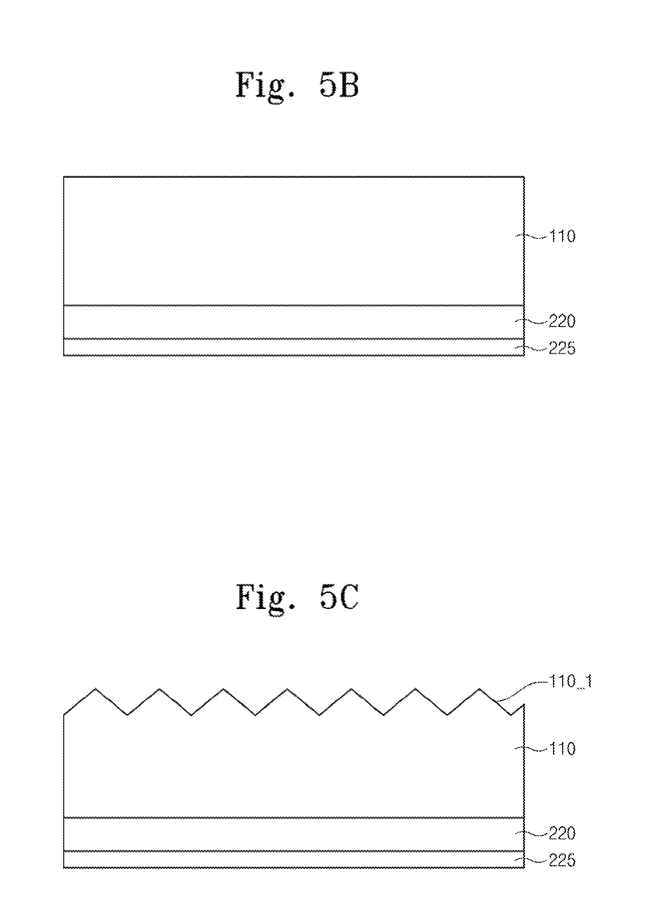

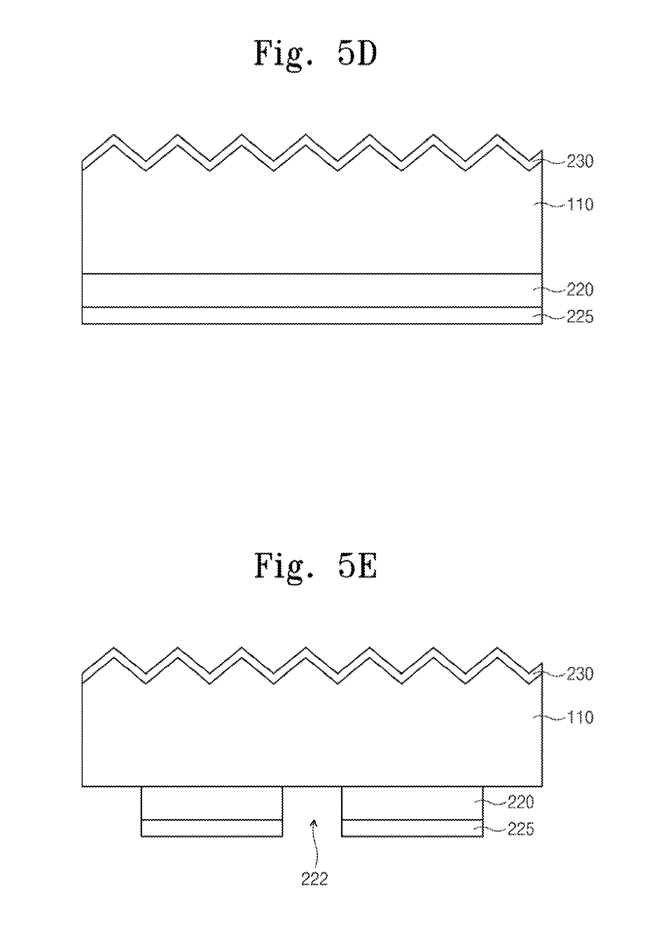

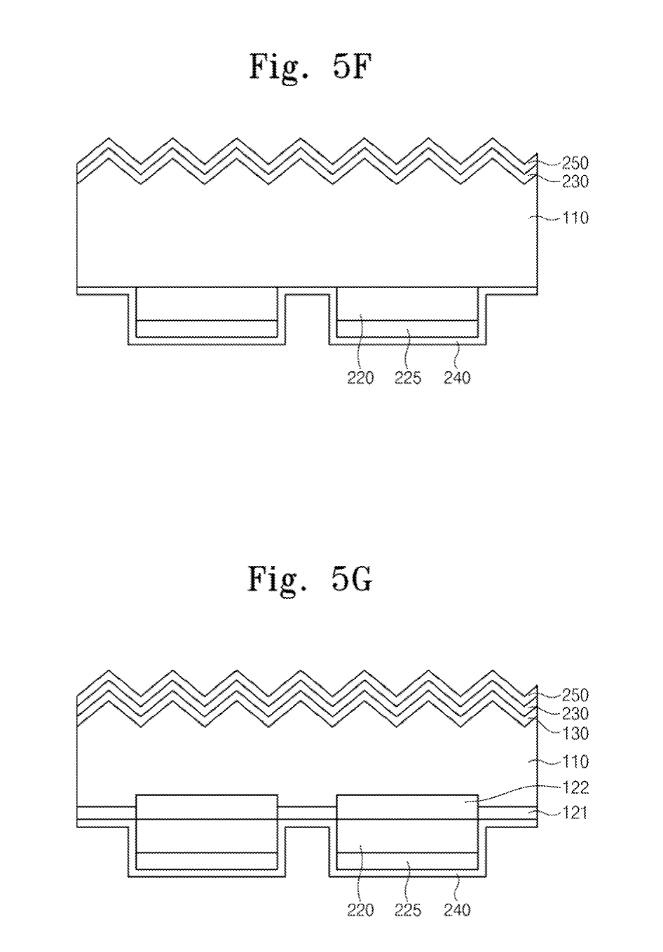

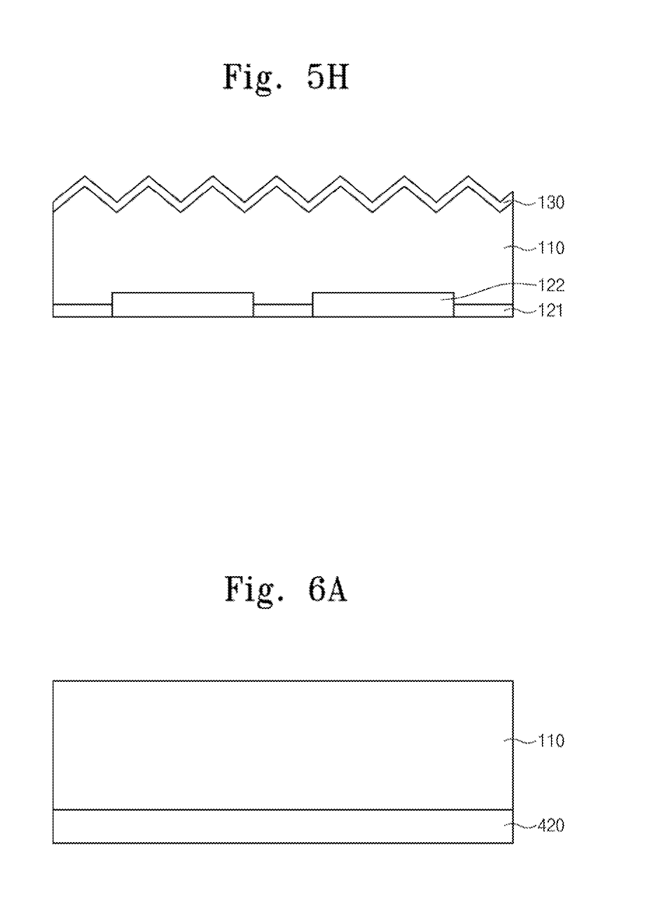

FIGS. 5A to 5H are sectional views showing a method of manufacturing a solar cell according to a second exemplary embodiment of the present invention. In FIGS. 5A to 5H, the same reference numerals denote the same elements in FIGS. 3A to 3N, and thus detailed description of these same elements will be omitted.

Referring to FIGS. 5A and 5B, a first dopant layer 220 is formed on a lower surface of the substrate 110, and a mask layer 225 is formed on the first dopant layer 220.

The mask layer 225 may be formed of silicon that is not doped with impurities, or undoped silicon. As an example, the mask layer 225 may be formed by a chemical vapor deposition process, but may also be formed by any other suitable process. The mask layer 225 may prevent the first dopant layer 220 from being removed during the texturing process whose results are shown in FIG. 5C. In addition, in FIG. 5B, the mask layer 225 has a thickness that is less than a thickness of the first dopant layer 220, although this need not necessarily be the case. That is, the thickness of the mask layer 225 can vary, at least according to the material used for the mask layer 225 and the texturing process.

Referring to FIG. 5C, the upper surface of the substrate 110 is textured to have pyramid shapes 110_1.

Referring to FIG. 5D, a diffusion-preventing layer 230 is formed on the textured upper surface of the substrate 110.

Referring to FIG. 5E, after the texturing process, the first dopant layer 220 and the mask layer 225 are patterned to form openings 222. In order to form the openings 222, a photoresist pattern (not shown) is formed on the mask layer 225. The first dopant layer 220 and the mask layer 225 are then etched using the photoresist pattern as a mask, thereby forming the openings 222.

Referring to FIG. 5F, a second dopant layer 240 is formed on the lower surface of the substrate to cover the first dopant layer 220 and the mask layer 225, and a third dopant layer 250 is formed on the diffusion-preventing layer 230. The second and third dopant layers 240 and 250 include n-type dopants. The second and third dopant layers 240 and 250 may be formed through the same processes described in the first exemplary embodiment.

Referring to FIG. 5G, semiconductor areas 121 and 122 and a recombination-preventing layer 130 are formed by processes like those described in connection with FIG. 3F.

Referring to FIGS. 5G and 5H, the first to third dopant layers 220, 240, and 250, the diffusion-preventing layer 230, and the mask layer 225 are all removed by using a hydrogen fluoride (HF) solution. This leaves the recombination-layer 130 and the semiconductor areas 121 and 122 exposed on the substrate 110.

In the second exemplary embodiment, subsequent processes are substantially the same as the processes described with reference to FIGS. 3H to 3N.

According to the second exemplary embodiment, the mask layer 225 is formed on the first dopant layer 220, so that the first dopant layer 220 may be prevented from being removed during the texture process. In addition, the recombination-preventing layer 130 and the n-type and p-type semiconductor areas 121 and 122 are formed by a single diffusion process. In addition, the anti-reflection layer 140 and the passivation layer 150 are formed through a single process. Accordingly, fabrication of the solar cell may be simplified, thereby improving the productivity and cost of the solar cell. In addition, since the anti-reflection layer 140 and the passivation layer 150 each have a single-layer structure of silicon nitride, the manufacturing cost for the solar cell may be reduced.

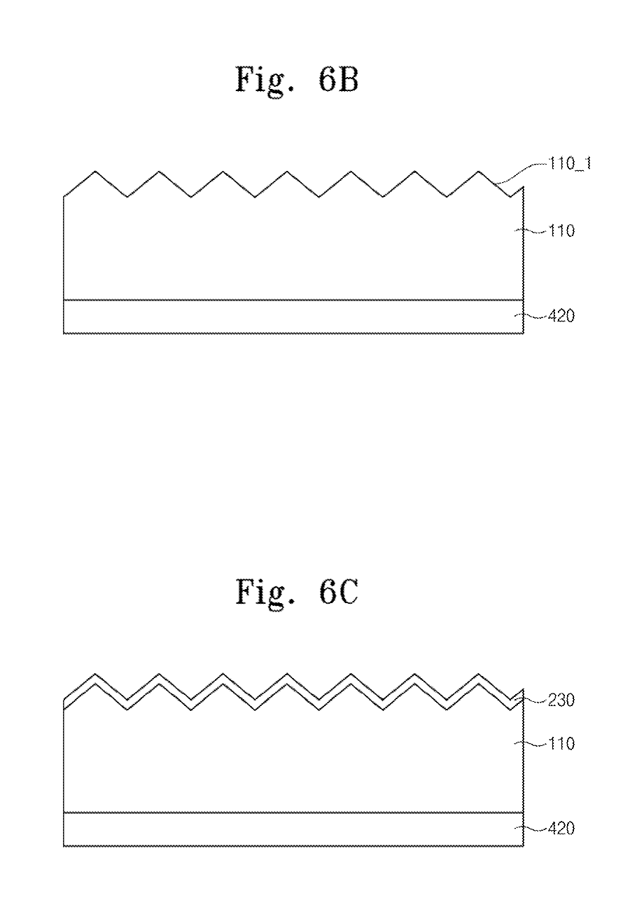

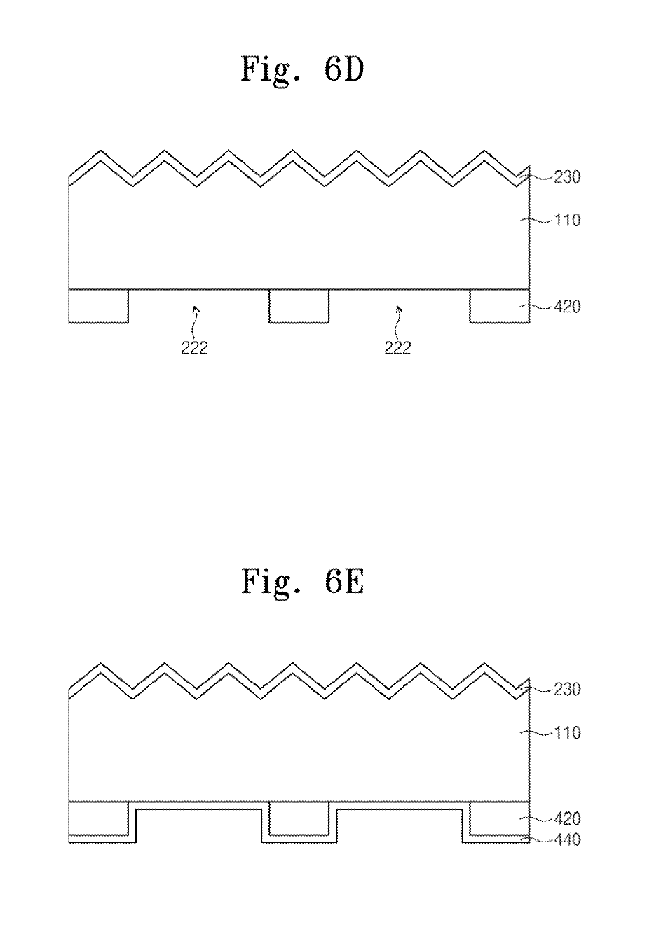

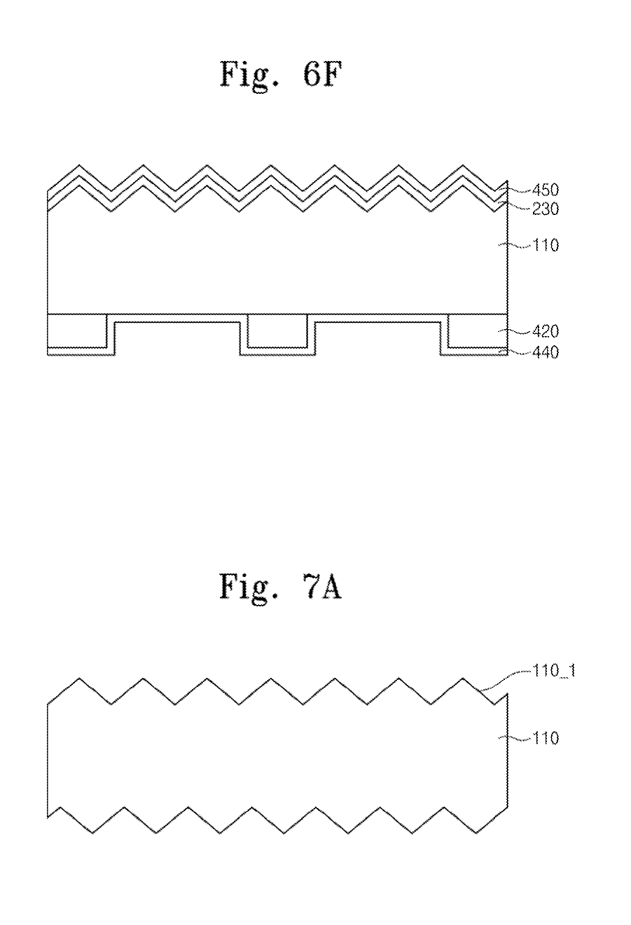

FIGS. 6A to 6F are sectional views showing a method of manufacturing a solar cell according to a third exemplary embodiment of the present invention.

Referring to FIG. 6A, a first dopant layer 420 is formed on a lower surface of a substrate 110. The first dopant layer 420 includes n-type dopants. As an example, the first dopant layer 420 may include phosphor, and may be a PSG layer. The first dopant layer 420 may have a thickness sufficient to leave enough of the dopant layer 420 undamaged by sodium hydroxide solution when the upper surface of the substrate 110 is textured. The first dopant layer 420 may be deposited by various semiconductor processes, such as by a chemical vapor deposition process, a sputtering process, an inkjet printing process, a screen printing process, a spin coating process, etc.

Referring to FIG. 6B, the upper surface of the substrate 110 is textured to form pyramid shapes 110_1. During the texture process, the lower surface of the substrate 110 is not textured, due to the presence of the first dopant layer 420.

Referring to FIG. 6C, a diffusion-preventing layer 230 is formed on the textured upper surface of the substrate 110. As an example, the diffusion-preventing layer 230 may be formed of silicon that is not doped with impurities. The diffusion-preventing layer 230 may prevent dopants in a third dopant layer from diffusing into the substrate 110 during the diffusion process described below.

Referring to FIG. 6D, the first dopant layer 420 is patterned to form openings 222 therethrough. The openings 222 are formed in areas in which the p-type semiconductor areas 122 are to be formed.

The openings 222 may be formed, for example, by using photolithography and etching processes. In detail, a photoresist (not shown) is coated on the first dopant layer 420, and the photoresist layer is exposed to light and developed to form a photoresist pattern (not shown). Then, the first dopant layer 220 is etched using the photoresist pattern as a mask to form the openings 222. In this case, the etching process for the first dopant layer 220 may be a wet etching process.

Referring to FIG. 6E, a second dopant layer 440 is formed on the lower surface of the substrate 110 to cover the first dopant layer 420. The second dopant layer 440 includes p-type dopants. In the present exemplary embodiment, the second dopant layer 440 may include boron and the second dopant layer 440 may be a BSG layer. The second dopant layer 440 may be deposited by various semiconductor processes, such as by a chemical vapor deposition process, a sputtering process, an inkjet printing process, a screen printing process, a spin coating process, etc.

Referring to FIG. 6F, a third dopant layer 450 is next formed on the diffusion-preventing layer 230. The third dopant layer 450 includes n-type dopants similar to the first dopant layer 420. In order to form the third dopant layer 450, the phosphoryl chloride (POCl₃) gas is diffused onto the substrate 110 using a chemical vapor deposition process at high temperature. The phosphoryl chloride (POCl₃) gas reacts with the diffusion-preventing layer 230, as well as the BSG layer.

In the third exemplary embodiment, subsequent processes are substantially the same as the processes described with reference to FIGS. 3F to 3N.

According to the third exemplary embodiment, the recombination-preventing layer 130 and the n-type and p-type semiconductor areas 121 and 122 are formed by the same diffusion process. In addition, the anti-reflection layer 140 and the passivation layer 150 are formed through one process. Accordingly, the manufacture of the solar cell may be simplified, thereby improving productivity and cost of the solar cell.

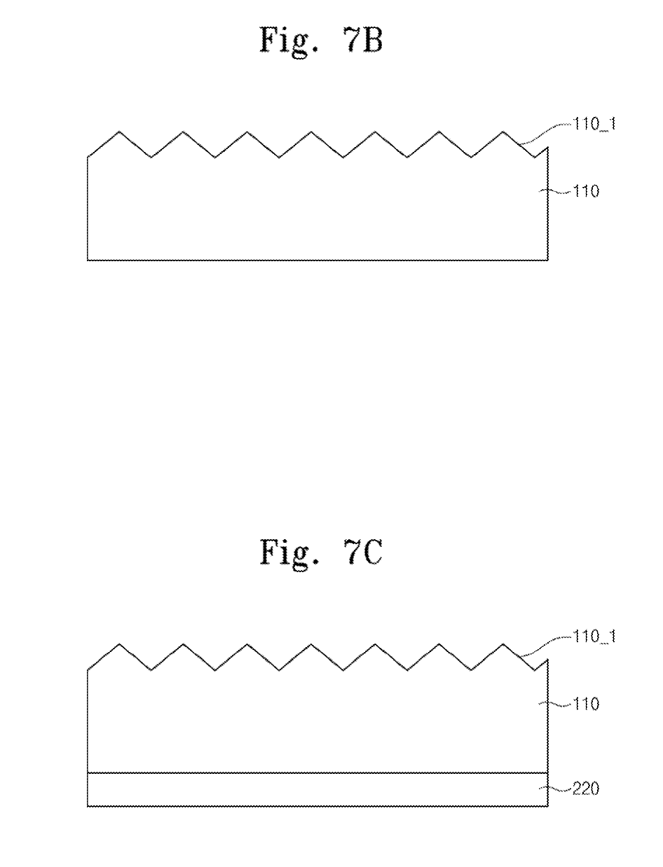

FIGS. 7A to 7C are sectional views showing a method of manufacturing a solar cell according to a fourth exemplary embodiment of the present invention.

Referring to FIG. 7A, the substrate 110 is textured to have pyramid shapes 110_1. The upper surface and the lower surface of the substrate 110 are both textured by a wet etching process, using a solution in which a sodium hydroxide solution and an isopropyl alcohol solution are mixed with each other.

Referring to FIG. 7B, the lower surface of the substrate 110 is flattened, such that the pyramid shapes 110_1 are formed only on the upper surface of the substrate 110. This flattening may be accomplished by dipping only the lower surface of the substrate 110 into etchant.

Referring to FIG. 7C, a first dopant layer is formed on the lower surface of the substrate 110. The first dopant layer 220 may include p-type dopants. Particularly, the first dopant layer 220 may include boron, and the first dopant layer may be a BSG layer.

In the fourth exemplary embodiment, subsequent processes are substantially the same as the processes described with reference to FIGS. 3C to 3N.

According to the fourth exemplary embodiment, although an additional flattening process is performed to flatten the lower surface of the substrate 110 after texturing, the first dopant layer 220 is still kept from being damaged, as the texturing process is performed before forming the first dopant layer 220. In addition, since the processes subsequent to forming the first dopant layer 220 are substantially the same as those described in the first exemplary embodiment, manufacture of the solar cell may be simplified, thereby improving its productivity and cost.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A method of manufacturing a solar cell, comprising:
forming a first dopant layer on a lower surface of a substrate;
forming a diffusion-preventing layer on an upper surface of the substrate;
patterning the first dopant layer to expose portions of the lower surface of the substrate;
forming a second dopant layer on the exposed portions of the lower surface of the substrate;
forming a third dopant layer on the diffusion-preventing layer; and
heating the substrate to diffuse dopants of the first, second, and third dopant layers into the substrate.

2. The method of claim 1, wherein the first dopant layer comprises p-type dopants and the second and third dopant layers comprise n-type dopants.

3. The method of claim 2, wherein the second dopant layer and the third dopant layer are formed during the same process.

4. The method of claim 2, further comprising, prior to the forming a diffusion-preventing layer, texturing the upper surface of the substrate, wherein the lower surface of the substrate is protected by the first dopant layer.

5. The method of claim 2, wherein the forming a first dopant layer further comprises forming a mask layer on the first dopant layer so as to protect the first dopant layer, wherein the mask layer and the first dopant layer are patterned during the same process.

6. The method of claim 4, wherein the mask layer comprises undoped silicon.

7. The method of claim 1, wherein the first and third dopant layers comprise n-type dopants and the second dopant layer comprises p-type dopants.

8. The method of claim 7, further comprising, prior to the forming a diffusion-preventing layer, texturing the upper surface of the substrate, wherein the lower surface of the substrate is protected by the first dopant layer.

9. The method of claim 1, further comprising texturing the upper surface of the substrate prior to forming the first dopant layer.

10. The method of claim 1, further comprising forming a plurality of semiconductor areas in the lower surface of the substrate.

11. The method of claim 10, further comprising forming a recombination-preventing layer on the upper surface of the substrate, wherein the recombination-preventing layer comprises n-type dopants.

12. The method of claim 11, further comprising removing the first, second, and third dopant layers and the diffusion-preventing layer.

13. The method of claim 12, further comprising:
forming a passivation layer on the semiconductor areas; and
forming an anti-reflection layer on the recombination-preventing layer.

14. The method of claim 13, wherein the anti-reflection layer comprises a same material as the passivation layer.

15. The method of claim 14, wherein the anti-reflection layer and the passivation layer both comprise silicon nitride.

16. The method of claim 1, wherein the diffusion-preventing layer comprises undoped silicon.

17. The method of claim 1, wherein the semiconductor areas comprise:
first semiconductor areas doped with a p-type dopant; and
second semiconductor areas doped with an n-type dopant,
wherein the first semiconductor areas are alternately arranged with the second semiconductor areas.

18. The method of claim 13, wherein the recombination-preventing layer has a doping concentration lower than a doping concentration of the second semiconductor areas.

19. The method of claim 18, further comprising forming a plurality of metal electrodes electrically connected to the semiconductor areas.

20. The method of claim 19, wherein the forming a plurality of metal electrodes comprises:
forming contact holes through the passivation layer to expose a portion of each of the semiconductor areas;
forming a metal layer on the exposed portions of the semiconductor areas;
forming a print-preventing layer on areas of the first metal layer corresponding to boundaries between the semiconductor areas;
forming second metal layers on the first metal layer;
removing the print-preventing layer; and
removing the first metal layer from areas from which the print-preventing layer has been removed.
